(19) United States
(12) Patent Application Publication
(10) Pub. No.: US 2025/0151480 A1
(43) Pub. Date: May 8, 2025

(54) OPTOELECTRONIC SEMICONDUCTOR COMPONENT, CONVERSION ELEMENT AND MANUFACTURING METHOD

(71) Applicant: AMS-OSRAM INTERNATIONAL GMBH, Regensburg (DE)

(72) Inventors: Michael ZITZLSPERGER, Regensburg (DE); Thomas SCHWARZ, Regensburg (DE)

(21) Appl. No.: 18/833,836

(22) PCT Filed: Jan. 12, 2023
(86) PCT No.: PCT/EP2023/050610

§ 371 Date: Jul. 26, 2024

(30) Foreign Application Priority Data
Jan. 27, 2022 (DE) 10 2022 101 910.1

(51) Int. Cl. H10H 20/851; H10H 20/01; H10H 20/85

(52) U.S. Cl. CPC H10H 20/8514; H10H 20/0361; H10H 20/8506

(57) ABSTRACT

In one embodiment, the optoelectronic semiconductor component comprises:—an optoelectronic semiconductor chip, and—a conversion element configured to convert at least part of a primary radiation emitted by the optoelectronic semiconductor chip during operation into a secondary radiation, wherein—the conversion element comprises a frame and a phosphor body within the frame,—the phosphor body comprises at least one phosphor and the frame contains at least one ceramic, and the frame is in direct contact with the phosphor body in a lateral direction which is oriented parallel to a main radiation side of the optoelectronic semiconductor chip.

An optoelectronic semiconductor component is provided. In addition, a conversion element and a manufacturing method for an optoelectronic semiconductor component are provided.

Document WO 2014/166948 A1 relates to an optoelectronic semiconductor component.

An object to be achieved is to provide an optoelectronic semiconductor component comprising a high light extraction efficiency.

This object is solved, inter alia, by an optoelectronic semiconductor component, by a conversion element and by a manufacturing method with the features of the independent patent claims. Preferred further developments are the subject of the dependent claims.

According to at least one embodiment, the semiconductor component comprises one or more optoelectronic semiconductor chips. The at least one optoelectronic semiconductor chip is based, for example, on a semiconductor layer sequence of AlₙIn₁₋ₙ₋ₘGaₘN, of AlₙIn₁₋ₙ₋ₘGaₘP, of AlₙIn₁₋ₙ₋ₘGaₘAs or of AlₙGaₘIn₁₋ₙ₋ₘAsₖP₁₋ₖ, where in each case 0≤n≤1, 0≤m≤1 and n+m≤1 as well as 0≤k<<1 and where the semiconductor layer sequence may contain dopants. The semiconductor layer sequence comprises at least one active layer configured to generate electromagnetic radiation. A radiation generated by the active layer during operation lies in particular in the spectral range between 380 nm and 520 nm, inclusive. Preferably, the semiconductor layer sequence is based on the material system AlₙIn₁₋ₙ₋ₘGaₘN. The semiconductor component can therefore be a light-emitting diode component.

If several of the optoelectronic semiconductor chips are present, all of the semiconductor chips can be of the same design or different types of semiconductor chips can be combined in the semiconductor component, for example, to generate light of different colors.

According to at least one embodiment, the semiconductor component comprises one or more conversion elements. The at least one conversion element is configured to convert at least a portion of a primary radiation emitted by the at least one optoelectronic semiconductor chip during operation into a secondary radiation. The at least one conversion element can thus be configured for partial conversion or alternatively for full conversion of the primary radiation.

If several of the conversion elements are present, all conversion elements can be of the same design or different types of conversion elements can be combined with each other in the semiconductor component, for example, to generate light of different colors or correlated color temperatures.

According to at least one embodiment, the at least one conversion element comprises a frame and at least one phosphor body within the frame. The phosphor body comprises one or more phosphors. If several of the phosphor bodies are present, all or some of the phosphor bodies may be accommodated in a common frame or a separate frame may be provided for each phosphor body.

According to at least one embodiment, the frame comprises one or more ceramics and/or at least one porcelain. Preferably, the frame is made of a single, homogeneous material.

According to at least one embodiment, the frame is in direct contact with the phosphor body in a lateral direction, which is preferably oriented parallel to a main radiation side of the optoelectronic semiconductor chip. This means that the phosphor body and the frame can touch each other in the lateral direction and can be molded to each other.

In at least one embodiment, the optoelectronic semiconductor component comprises an optoelectronic semiconductor chip and a conversion element configured to convert at least a portion of a primary radiation emitted from the optoelectronic semiconductor chip during operation into a secondary radiation. The conversion element comprises a frame and a phosphor body within the frame. The phosphor body comprises at least one phosphor and the frame contains at least one ceramic. The frame is in direct contact with the phosphor body in a lateral direction, which is preferably oriented parallel to a main radiation side of the optoelectronic semiconductor chip. For example, the frame comprises at least one recess and a bonding wire is located at least partially in the recess and the recess is located next to the phosphor body as seen in plan view of the main radiation side, wherein the recess only partially penetrates the frame in a direction perpendicular to the main radiation side.

In white-emitting light-emitting diodes, or LEDs for short, a ceramic conversion element, also known as a phosphor platelet, is often used to convert blue light to yellow light. Light is also emitted from side surfaces of the conversion element, which is generally undesirable. In the semiconductor component described here, the conversion element is provided with a preferably ceramic, reflective frame. Another problem is that a wire contact can be damaged during the handling of LED components by a customer if a component surface is made of soft silicone.

In order to prevent light from escaping laterally from the conversion element, in an alternative configuration the actual phosphor body, after it has been applied to an LED chip, is either encapsulated with the LED chip underneath and optionally with the bonding wires, for example, in silicone with reflective metal oxide particles, such as Tio₂ or Zro₂ particles, or encapsulated in a white or black material in an injection molding process, for example, in an epoxy comprising inorganic fillers. The surrounding material and the manufacturing process determine the mechanical properties of the component, that is, the solid or soft environment of the conversion element and the bonding wire, how stable the reflection properties are with regard to possible delamination of the environment from the conversion element and how high the contrast is, that is, in particular the penetration depth of the light into the surrounding medium.

In the semiconductor component described here, the conversion element is provided with a hard, reflective edge or frame before it is mounted on the semiconductor chip, which is in particular an LED chip. Since this is done during the production of the conversion element, high temperatures and thus the use of ceramic materials, such as porcelain in the case of transparent plates, are possible. The optical properties of this frame can be selected over a wide range and the shape of the frame is largely freely designable. The phosphor body frame component can therefore also take on the functionalities of LED housing.

Conventionally, a conversion element is therefore homogeneous and without a reflective edge. Only a subsequently applied white casting or injection-molded body in a housing prevents light from escaping laterally. In contrast, in the semiconductor component described here, the phosphor body is already provided with a reflective edge or frame made of a ceramic material during producing. This also allows for extending the phosphor body, in particular a light-emitting surface, with a cost-effective material, right up to a housing body, and to provide the phosphor body with a colored or metallic layer, for example, made of platinum, without complex processes.

The ceramic frame can be attached to the phosphor body before sintering, in particular as a green body, or afterwards. Porcelain is a suitable ceramic material. Depending on whether a casting process, a pressing process or an injection molding process is used, the porcelain mass can be produced in liquid form, for example, as a slip, for casting in molds or for high-pressure pressing, as a mass with varying degrees of pliability, in particular for pressing or plastic molding, or even as dry granules, in particular for dry pressing.

The frame, which is, for example, a porcelain body, can be left relatively porous so that, for example, a later casting or mold body can adhere well to it, or so that the frame can be provided with a glaze, for example, in a mono-firing method, or can also be given a colored or metallic coating. In addition, many small pores can ensure high diffusion and reflectivity.

Thus, the conversion element preferably has a mechanically robust frame that can serve as part of the housing of the semiconductor component and can optionally mechanically protect a bonding wire. The risk of delamination between the conversion element and an optional casting is significantly reduced. Several conversion elements for a multi-chip component can be combined to form a single component. The frame can be provided with a glaze so that colored surfaces are possible, such as a black surface for a high contrast in a multi-chip component, for example, for automotive headlights. This colored decoration can be very finely structured, for example, black around a field with the semiconductor chips and transparent between the semiconductor chips.

According to at least one embodiment, the frame directly surrounds the phosphor body on all sides when viewed from above on the main radiation side. This means that the frame can form a completely closed path directly around the phosphor body. Side surfaces of the phosphor body, which are oriented transversely to the main radiation side, can be completely covered by the frame, in particular the entire surface can be in physical contact with the frame.

According to at least one embodiment, a material of the frame, in particular the at least one ceramic of the frame, is opaque. Alternatively or additionally, the frame is provided with an opaque coating. Opaque means, for example, that a transmission coefficient for visible light through the frame, in particular in the direction perpendicular to the main radiation side, is at most 5% or at most 1% or at most 0.1%. Visible light refers in particular to the spectral range from 420 nm to 720 nm.

According to at least one embodiment, a thickness of the frame is greater than or equal to a thickness of the phosphor body. In other words, the frame can project beyond the phosphor body in the direction towards the at least one optoelectronic semiconductor chip and/or in the direction away from the at least one optoelectronic semiconductor chip.

In particular, the frame can be thicker directly on the phosphor body than the phosphor body.

According to at least one embodiment, the conversion element is configured to be traversed by the primary radiation and/or by the secondary radiation in a direction transverse to the main radiation side. In other words, the conversion element is configured for transmission operation. A main radiation direction of the at least one optoelectronic semiconductor chip can be the same as a main radiation direction of the conversion element.

According to at least one embodiment, a reflectivity of the frame, in particular of the ceramic of the frame, for the secondary radiation and/or for the primary radiation and/or for visible light is at least 95% or at least 98%. As a result, a high light radiation efficiency of the semiconductor component can be achieved.

According to at least one embodiment, the ceramic of the frame comprises a base material. For example, the base material is Al₂O₃ and/or AlN.

According to at least one embodiment, the base material comprises at least one admixture having a reflective effect for the primary radiation and/or for the secondary radiation and/or for visible light. For example, the admixture is at least one metal oxide. The metal oxide can be present in the form of reflective particles distributed homogeneously in the base material. In particular, the metal oxide is ZrO₂ and/or TiO₂. This means that a material that is transparent in itself, such as Al₂O₃ or AlN, can become diffusely reflective by adding Zro₂ or TiO₂. A mass fraction of the at least one addition to the frame is, for example, at least 0.5% and/or at most 5%.

According to at least one embodiment, the frame partially covers the main radiation side when viewed from above. In other words, the frame then partially covers the at least one optoelectronic semiconductor chip. Alternatively, the at least one optoelectronic semiconductor chip is not covered by the frame, so that the main radiation side and the frame can be geometrically disjunct.

This means, for example, that the frame can extend to a side of the phosphor body facing away from the at least one optoelectronic semiconductor chip.

According to at least one embodiment, the frame projects beyond the optoelectronic semiconductor chip on all sides.

The frame can thus comprise larger lateral dimensions than the at least one optoelectronic semiconductor chip.

According to at least one embodiment, the optoelectronic semiconductor component comprises one or more bonding wires. The optoelectronic semiconductor chip is electrically contacted with the at least one bonding wire. If the at least one optoelectronic semiconductor chip is a flip chip with electrical contact surfaces facing away from the conversion element, electrical contacting of the at least one optoelectronic semiconductor chip can be made without a bonding wire.

According to at least one embodiment, the frame comprises one or more recesses. The at least one bonding wire is located at least partially, in particular only partially, in the recess. If several bonding wires are present, a separate recess may be provided for each of the bonding wires. Alternatively, a common recess is provided for all or several of the bonding wires.

According to at least one embodiment, the recess is located partially or completely next to the phosphor body when viewed from above on the main radiation side. In particular, a material of the frame is located continuously between the at least one recess and the phosphor body, so that the at least one recess is arranged at a distance from the phosphor body.

According to at least one embodiment, the recess only partially penetrates the frame in the direction perpendicular to the main radiation side. This means that the recess can be a blind hole. The recess is then preferably not visible from a side of the frame facing away from the at least one optoelectronic semiconductor chip. For example, the recess extends through the frame in the direction perpendicular to the main radiation side for at least 40% or at least 50% or at least 60% of the frame. Alternatively or additionally, the recess extends for at most 90% or at most 80% through the frame.

According to at least one embodiment, the at least one bonding wire or one of the bonding wires or several of the bonding wires or all of the bonding wires in the recess run parallel to the main radiation side with a tolerance of at most 60° or at most 45° or at most 30° or at most 15°. This applies, for example, to a proportion of the at least one relevant bonding wire in the associated recess of at least 70% or at least 80% or at least 90%, viewed in a direction parallel to the main radiation side.

According to at least one embodiment, the recess completely penetrates the frame in places or entirely in the direction perpendicular to the main radiation side. In places means that the recess is partially covered by a material of the frame, in the direction away from the main radiation side. Accordingly, entirely means that the entire recess is accessible from a side facing away from the main radiation side and/or is not covered by a material of the frame and/or is not visible.

If several of the recesses are present, different types of recesses can be combined with each other, that is, in particular recesses that completely penetrate the frame and recesses that only partially penetrate the frame.

According to at least one embodiment, the frame comprises one or more cavities on a side of the phosphor body facing away from the optoelectronic semiconductor chip. In contrast to the at least one recess, the at least one cavity is thus not only located next to, but partially or completely located on the phosphor body, seen in plan view on the main radiation side.

According to at least one embodiment, the frame surrounds the cavity all around in the lateral direction. In other words, the cavity is defined by the frame and surrounded all around by the frame.

According to at least one embodiment, the optoelectronic semiconductor component comprises one or more window bodies. The at least one window body is transmissive for the secondary radiation and/or for the primary radiation and/or for visible light. Transmissive means in particular that a transmission coefficient for the relevant radiation is at least 70% or at least 90% or at least 95%.

According to at least one embodiment, the phosphor body is attached directly to the window body. For example, the phosphor body has been deposited and/or produced on the window body. This means that the window body can be a carrier for the phosphor body. In particular, the phosphor body is not mechanically self-supporting without the window body.

According to at least one embodiment, the window body is in direct contact with the frame in the lateral direction. Lateral boundary surfaces of the window body can be directly and completely covered by the frame.

If several of the window bodies are present, different types of window bodies can be combined with each other or all window bodies are of the same design. It is then possible for all or some of the window units to be accommodated in a common frame.

According to at least one embodiment, the optoelectronic semiconductor component comprises one or more optical bodies. The at least one optical body is transparent for secondary radiation and/or for primary radiation and/or for visible light. For example, the optical body is a lens, such as a converging lens. Several optical bodies can be combined with each other.

According to at least one embodiment, the optical body partially or completely fills the associated cavity and/or partially or completely covers the associated cavity. It is possible that the at least one optical body is applied directly to the associated phosphor body and/or to the associated window body. Preferably, the at least one optical body is in direct contact with the frame.

According to at least one embodiment, the cavity and/or the frame widens in the direction away from the at least one optoelectronic semiconductor chip. For example, the cavity and/or the frame are truncated cone-shaped or truncated pyramid-shaped with respect to an outer shape.

According to at least one embodiment, the optoelectronic semiconductor component comprises a carrier. The carrier may be an electrical connection part of the semiconductor component and/or the component mechanically supporting the semiconductor component. For example, the carrier is made of a ceramic that is provided with electrical conductor structures. The carrier can be an electrical circuit board.

According to at least one embodiment, the frame comprises one or more sockets. The socket is preferably made of the same material as the rest of the frame. Alternatively, the socket of the frame may be made of a different material than the parts of the frame that are directly attached to the at least one phosphor body.

According to at least one embodiment, the at least one socket and the at least one optoelectronic semiconductor chip are mounted together on the carrier. By means of the at least one socket, a distance between the phosphor body and the associated semiconductor chip can be set.

According to at least one embodiment, the phosphor body comprises at least one ceramic. This means, for example, that the phosphor of the phosphor body is a ceramic, that is, a ceramic phosphor, or that the phosphor body comprises a ceramic matrix material in which the phosphor is embedded. In the latter case, the phosphor can be a ceramic phosphor, although this is not essential.

In the case of a ceramic phosphor, for example, the thickness of the phosphor body is at least 30 μm or at least 100 μm and/or at most 0.5 mm or at most 0.2 mm.

According to at least one embodiment, the phosphor body comprises at least one polysiloxane as matrix material and phosphor particles comprising the at least one phosphor embedded therein. The phosphor can in turn be a ceramic phosphor, although other inorganic or organic phosphors are also conceivable.

In the case of a polysiloxane-based phosphor, for example, the thickness of the phosphor body is at least 3 μm or at least 5 μm and/or at most 50 μm or at most 20 μm.

In addition, a conversion element for an optoelectronic semiconductor component as described in connection with one or more of the above embodiments is disclosed. Features of the conversion element are therefore also disclosed for the optoelectronic semiconductor component and vice versa.

In at least one embodiment, the conversion element is configured to convert at least a portion of a primary radiation emitted by an optoelectronic semiconductor chip during operation into a secondary radiation. The conversion element comprises a frame and a phosphor body within the frame. The phosphor body comprises at least one phosphor and the frame contains at least one ceramic. The frame is in direct contact with the phosphor body in a lateral direction. The conversion element is configured to be operated in transmission.

In addition, a method of producing an optoelectronic semiconductor component as described in connection with one or more of the above embodiments is specified. Features of the optoelectronic semiconductor component are therefore also disclosed for the method and vice versa.

In at least one embodiment, the method is for producing an optoelectronic semiconductor component and comprises the following steps, in particular in the order given:
A) providing a plurality of the phosphor bodies,
B) providing a plurality of the frames,
C) singulating to form the conversion elements.

According to at least one embodiment, the phosphor bodies and the frames are sintered together.

According to at least one embodiment, step A) comprises:
A1) providing a first composite with a plurality of the phosphor bodies, and
A2) dividing the first composite into the individual phosphor bodies, wherein relative positions of the phosphor bodies with respect to each other are maintained until after step B).

Alternatively or additionally, according to at least one embodiment, step B) comprises:
B1) providing a second composite with a plurality of the frames directly to the previously provided phosphor bodies.

According to at least one embodiment, step A) comprises:
A3) Providing individual green bodies for the phosphor bodies,
A4) placing the green bodies in a mold.

Alternatively or additionally, according to at least one embodiment, step B) comprises:
B2) forming an engobe around the green bodies in the mold.

In the following, an optoelectronic semiconductor component described herein, a conversion element described herein and a method described herein are explained in more detail with reference to the drawing by means of exemplary embodiments.

Identical reference signs specify identical elements in the individual figures. However, no references are shown to scale; rather, individual elements may be shown in exaggerated size for better understanding.

### IN THE FIGURES

FIG. 1 is a schematic sectional view of a modification of an optoelectronic semiconductor component,

FIG. 2 is a schematic perspective view of the optoelectronic semiconductor component of FIG. 1,

FIG. 3 is a schematic sectional view of an exemplary embodiment of an optoelectronic semiconductor component described here,

FIG. 4 is a schematic top view of the optoelectronic semiconductor component of FIG. 3,

FIGS. 5 and 6 are schematic sectional views of a phosphor body and a frame for optoelectronic semiconductor components described here,

FIG. 7 is a schematic sectional view of an exemplary embodiment of an optoelectronic semiconductor component described here,

FIG. 8 is a schematic top view of the optoelectronic semiconductor component of FIG. 7,

FIG. 9 is a schematic sectional view of an exemplary embodiment of an optoelectronic semiconductor component described here,

FIG. 10 is a schematic top view of the optoelectronic semiconductor component of FIG. 9,

FIG. 11 is a schematic sectional view of an exemplary embodiment of an optoelectronic semiconductor component described here,

FIG. 12 is a schematic top view of the optoelectronic semiconductor component of FIG. 11,

FIG. 13 a schematic sectional view of an exemplary embodiment of an optoelectronic semiconductor component described here,

FIG. 14 is a schematic top view of the optoelectronic semiconductor component of FIG. 13,

FIG. 15 is a schematic sectional view of an exemplary embodiment of an optoelectronic semiconductor component described here,

FIG. 16 is a schematic top view of the optoelectronic semiconductor component of FIG. 15,

FIG. 17 a schematic sectional view of an exemplary embodiment of an optoelectronic semiconductor component described here,

FIG. 18 is a schematic top view of the optoelectronic semiconductor component of FIG. 17,

FIGS. 19 to 21 are schematic sectional views of exemplary embodiments of conversion elements for optoelectronic semiconductor components described herein,

FIGS. 22 to 25 are schematic top views of exemplary embodiments of optoelectronic semiconductor components described herein,

FIG. 26 is a schematic block diagram of an exemplary embodiment of a manufacturing process for optoelectronic semiconductor components described herein,

FIG. 27 is a schematic top view of a process step of an exemplary embodiment of a manufacturing process for optoelectronic semiconductor components described herein,

FIG. 28 is a schematic sectional view of FIG. 27,

FIGS. 29 to 31 are schematic sectional views of process steps of an exemplary embodiment of a manufacturing process for optoelectronic semiconductor components described herein,

FIGS. 32 to 34 are schematic sectional views of process steps of an exemplary embodiment of a manufacturing process for optoelectronic semiconductor components described herein,

FIG. 35 is a schematic sectional view of a process step of an exemplary embodiment of a manufacturing process for optoelectronic semiconductor components described herein, and

FIGS. 36 and 37 are schematic sectional views of process steps of an exemplary embodiment of a manufacturing process for optoelectronic semiconductor components described herein.

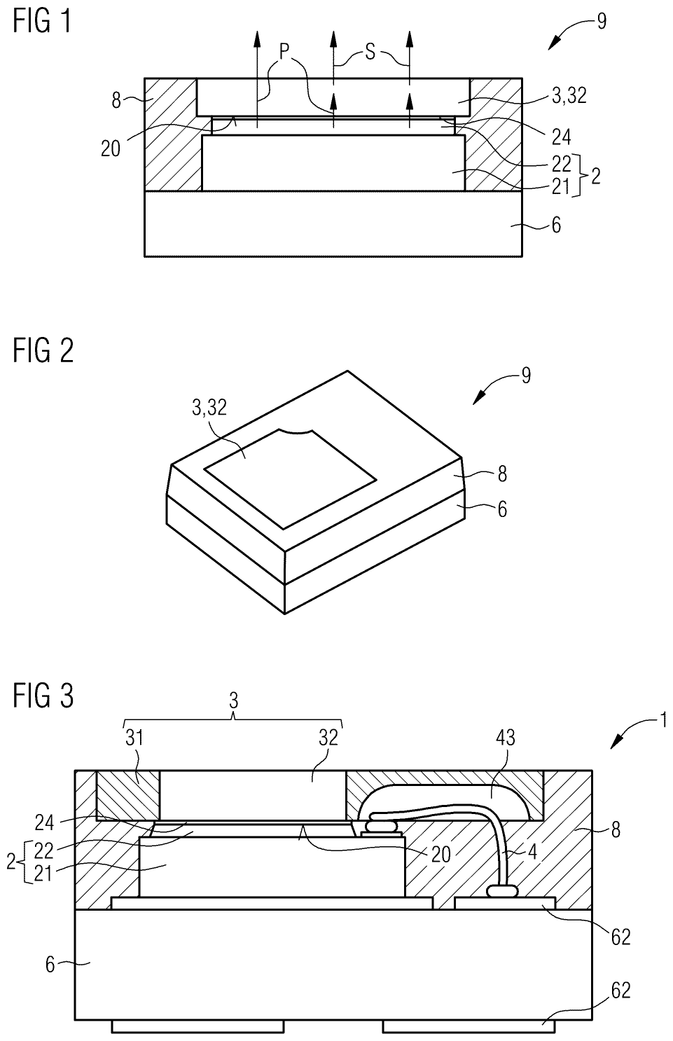

FIGS. 1 and 2 illustrate a modification 9 of a semiconductor component. The modification 9 comprises an optoelectronic semiconductor chip 2, in particular an LED chip, which is configured to generate a primary radiation P. The semiconductor chip 2 comprises, for example, a chip substrate 21 and a semiconductor layer sequence 22 applied thereto.

The primary radiation P is partially or alternatively completely converted into secondary radiation S in a phosphor 32 of a conversion element 3. In particular, a mixture of the primary radiation P and the secondary radiation S is emitted by the conversion element 9. The conversion element 3 is attached to a main radiation side 20 of the semiconductor chip 2, for example, by means of a connecting means 24, such as a silicone adhesive.

The semiconductor chip 2 and the conversion element 3 are directly surrounded by a plastic encapsulation 8 in a lateral direction, perpendicular to the main radiation side 20. The plastic encapsulation 8 is white, for example, and may be made of a silicone with reflective metal oxide particles embedded therein.

Optionally, the modification 9 comprises a carrier 6 to which the semiconductor chip 2 and the plastic encapsulation 8 are attached.

The secondary radiation in particular comprises a relatively large penetration depth into the plastic encapsulation 8. For example, the penetration depth is several 10 μm. This can result in undesirable light radiation on the plastic encapsulation 8. There is also a risk that the plastic encapsulation 8, which is only produced after the conversion element 3 has been fitted, will delaminate from the conversion element 3 due to thermal or radiation effects.

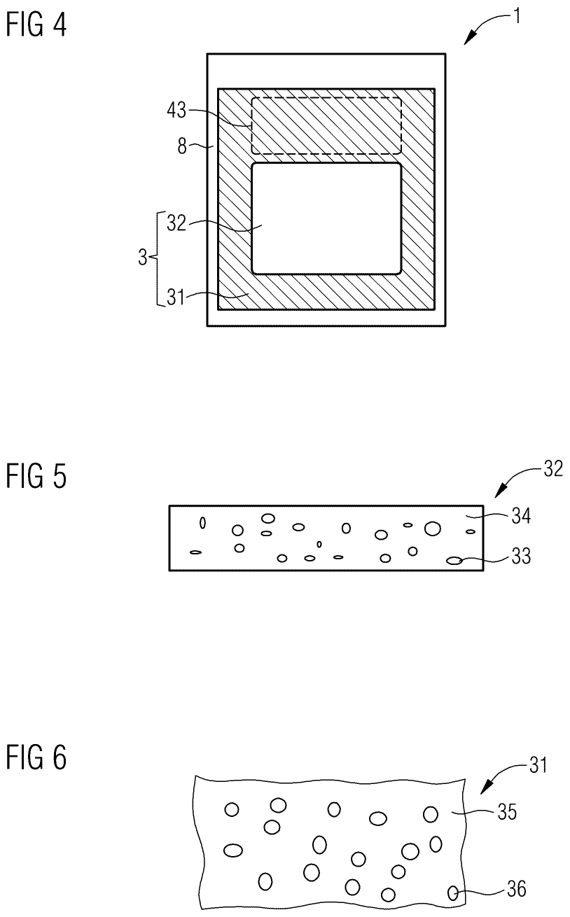

In order to remedy these problems, the exemplary embodiment of the optoelectronic semiconductor component 1 as shown in FIGS. 3 and 4 comprises a conversion element 3, which is composed of the phosphor body 32 and a frame 31. The frame 31 is made of a reflective ceramic and is molded directly onto the phosphor body 32 in the lateral direction all around.

The frame 31 partially covers the semiconductor chip 2 and protrudes laterally over the semiconductor chip 2. In the direction perpendicular to the main radiation side 20, the frame 31 and the phosphor body 32 are flush with each other and are therefore of the same thickness. The frame 31 and the phosphor body 32 thus extend on a side facing the semiconductor chip 2 approximately in the same plane as the main radiation side 20, since the connecting means 24 is very thin with a thickness of, for example, at most 5 μm or at most 3 μm.

Optionally, the semiconductor chip 2 is electrically contacted with a bonding wire 4, whereby a current conduction within the semiconductor chip 2 is not drawn in detail to simplify the illustration. For contacting the semiconductor chip 2, the bonding wire 4 and the semiconductor component 1, the optional carrier 6 comprises a plurality of electrical connection surfaces 62.

To enable that the bonding wire 4 can be guided to a side of the semiconductor chip 2 facing away from the optional carrier 6, the frame 31 comprises a recess 43 in which the bonding wire 43 is partially located. The recess 43 only partially penetrates the frame 31, so that the recess 43 is not visible when viewed from above. Due to this design of the recess 43, the bonding wire 4 can be efficiently protected from external influences.

As a further option, the semiconductor component 1 comprises the plastic encapsulation 8. The plastic encapsulation 8 can be of reflective white. The semiconductor chip 2 and the conversion element 3 are embedded in the plastic encapsulation 8. It is possible for the plastic encapsulation 8 and the conversion element to be flush with each other in the direction away from the semiconductor chip 2.

FIG. 5 schematically illustrates a possible phosphor body 32. The phosphor body 32 comprises phosphor particles 33. Optionally, the phosphor particles 33 are embedded in a matrix material 34. The matrix material 34 is preferably a ceramic, for example Al₂O₃ or AlN. The phosphor particles 33 can also be made of a ceramic material. In the case of ceramic phosphor particles 33, the phosphor body 32 can optionally also consist of the phosphor particles 33, so that no matrix material is then present. A thickness of the phosphor body 32 is, for example, between 80 μm and 200 μm inclusive.

For example, the phosphor particles 33 comprise one or more phosphors from the following group: Eu²⁺ doped nitrides such as (Ca, Sr) AlSiN₃:Eu²⁺, Sr(Ca, Sr) Si₂Al₂N₆:Eu²⁺, (Sr, Ca) AlSiN₃*Si₂N₂O:Eu²⁺, (Ca, Ba, Sr)₂Si₅Ng:Eu²⁺, (Sr, Ca) [LiAl₃N₄]:Eu²⁺; garnets from the general system (Gd, Lu, Tb, Y)₃(Al, Ga, D)₅(O, X)₁₂:RE with X=halide, N or divalent element, D=trivalent or tetravalent element and RE=rare earth metals, such as Lu₃(Al₁₋ₓGaₓ)₅O₁₂:Ce³⁺, Y₃(Al₁₋ₓGaₓ)₅O₁₂:Ce³⁺; Eu²⁺ doped SiONs such as (Ba, Sr, Ca) Si₂O₂N₂:Eu²⁺; SiAlONs such as from the system LiₓM_{y}Ln_{z}Si₁₂₋₍ₘ₊ₙ₎ Al(m+n)OnN₁₆₋ₙ; beta-SiAlONs from the system Si₆₋ₓAl_{z}O_{y}N_{8-y}:RE_{z} with RE=rare earth metals; nitrido-orthosilicates such as AE₂₋ₓ₋ₐREₓEuaSiO₄₋ₓNₓ or AE₂₋ₓ₋ₐREₓEuₐSi_{1-y}O_{4-x-2y}Nₓ Nₓ with RE=rare earth metal and AE=alkaline earth metal or such as (Ba, Sr, Ca, Mg)₂SiO₄:Eu²⁺, so-called quantum dots can also be used. Furthermore, the phosphor can comprise a quantum well structure and be epitaxially grown.

FIG. 6 schematically illustrates a possible internal structure of the frame 31. The frame 31 comprises a base material 35, for example Al₂O₃ or AlN. This means that the base material 35 alone can be transparent to visible light. In order to achieve a high reflectivity of the frame 31, an admixture 36 is preferably present, which can be homogeneously distributed in the base material 35. The admixture 36 is formed, for example, from particles of Zro₂ or TiO₂, so that the frame can be diffusely reflective in white.

Alternatively or in addition to the admixture 36, there may be unfilled pores or pores filled with a gas that cause the reflectivity of the frame 32. This applies equally in all other exemplary embodiments.

By using in particular a nanoporous ceramic for the frame 31, a high reflectivity can be achieved on the frame 31, in particular a higher reflectivity than with a plastic encapsulation 8, as shown in FIGS. 1 and 2. Due to the hard component surface on account of the frame 31 above the bonding wire 4, the bonding wire 4 can be effectively protected against mechanical damage. The risk of delamination between the phosphor body 32 and the plastic encapsulation 8 is eliminated. Additional lateral heat dissipation via the frame 31 provides increased cooling of the phosphor body 32. Furthermore, a high contrast, for example for headlight light sources, can be achieved by using a black material for the optional plastic encapsulation 8.

In all other respects, the comments on FIGS. 1 and 2 apply in the same way to FIGS. 3 to 6, and vice versa.

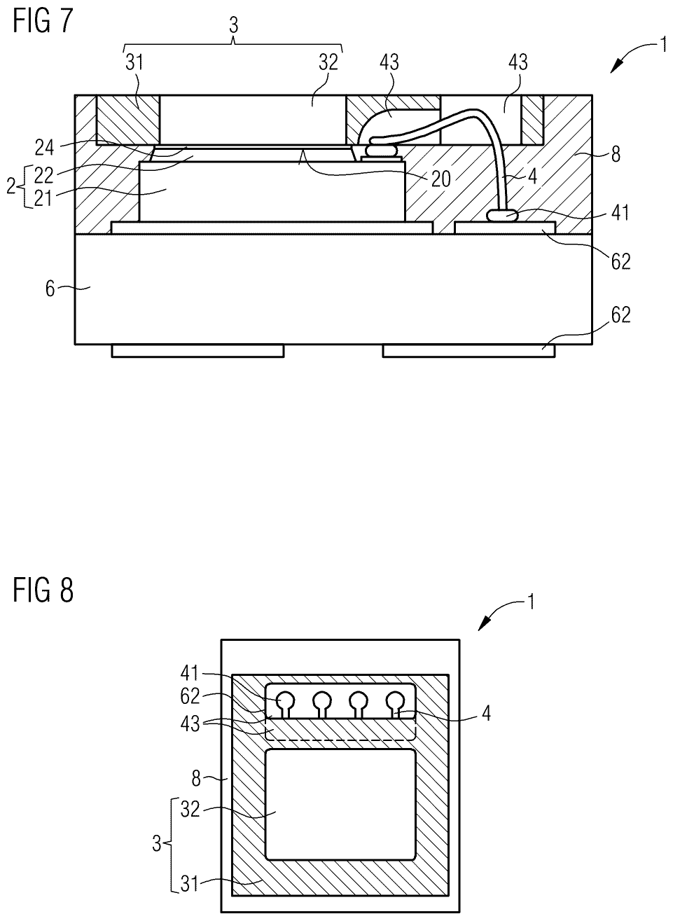

In the example of FIGS. 7 and 8, the recess 43 completely penetrates the frame 31 in places. This makes it possible for contact points 41 between the bonding wires 4 and the connection surfaces 62 to be exposed, at least temporarily, when viewed from above.

The recess 43 preferably comprises an area close to the phosphor body 32 in which the associated bonding wire 4 is covered by the frame 31. The combination of the covered area and the area completely penetrating the frame 31 reduces the overall thickness of the frame 31.

As an option, it can also be seen in FIG. 8 that several of the bonding wires 8 can be arranged parallel to one another. All bonding wires 8 can originate from the same connection surface 62.

Furthermore, the plastic encapsulation 8 is optionally present again, which can partially or completely fill the recess 43.

In all other respects, the comments on FIGS. 1 to 6 apply in the same way to FIGS. 7 and 8, and vice versa.

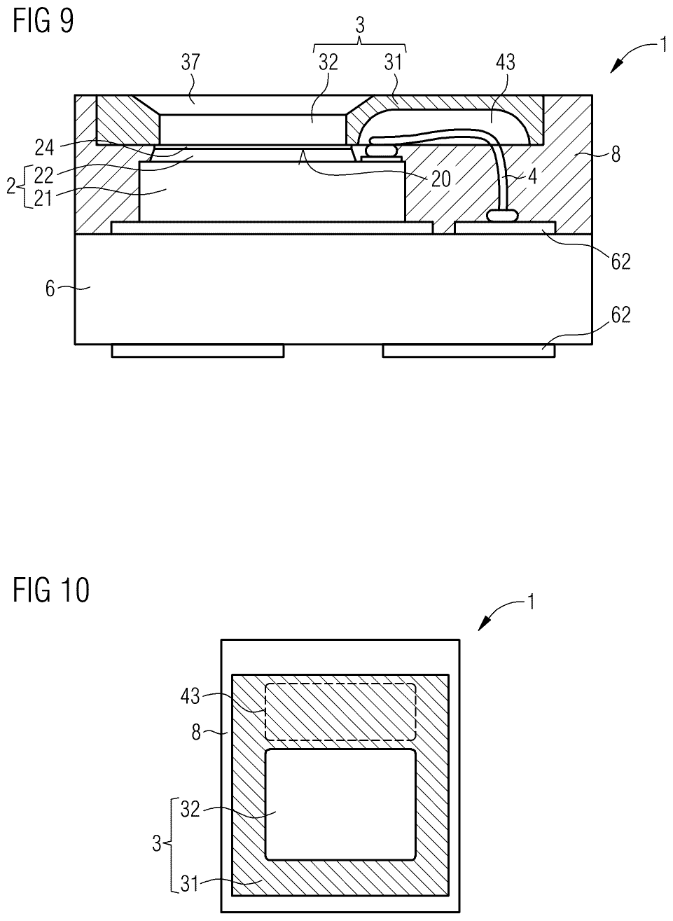

In the example of FIGS. 9 and 10, the frame 31 forms a cavity 37 on a side of the phosphor body 32 facing away from the semiconductor chip 2. It is possible that the cavity 37 widens in the direction away from the phosphor body 32. This means that the frame 31 protrudes beyond the phosphor body 32 on the side facing away from the semiconductor chip 2, but is flush with the phosphor body 32 towards the semiconductor chip 2. The cavity 37 is shaped, for example, like a truncated cone or a truncated pyramid or a mixture of these.

Due to the cavity 37 above the phosphor body 32, the ceramic frame 31 can be thicker overall, whereby increased mechanical stability can be achieved and more space is available for the at least one bonding wire 4. In addition, the cavity 37 above the phosphor body 32 can be used for further casting or can also be used for casting a lens, not shown in FIGS. 9 and 10.

In all other respects, the comments on FIGS. 1 to 8 apply in the same way to FIGS. 9 and 10, and vice versa.

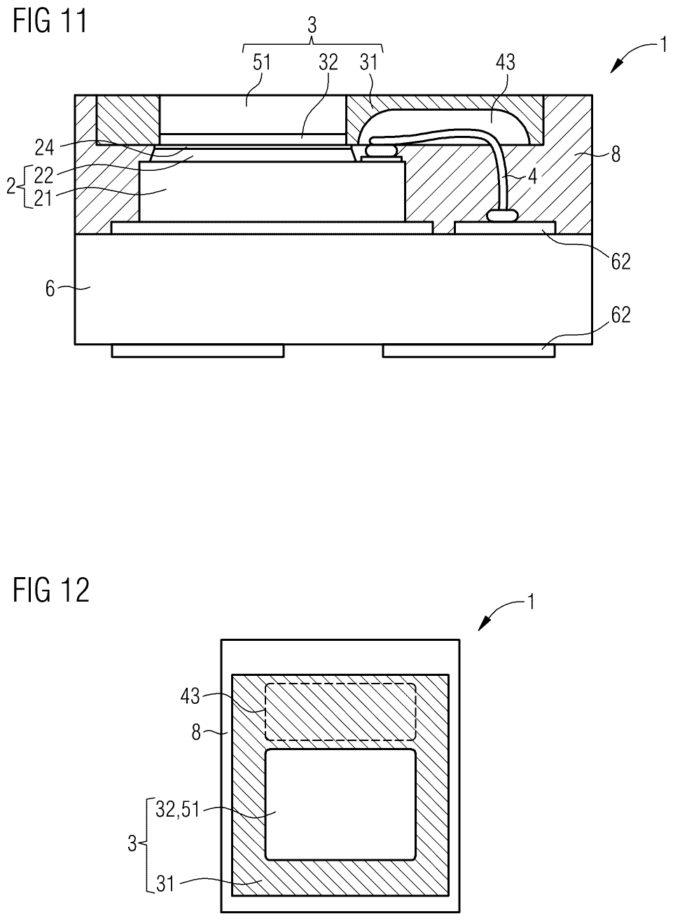

In the example of FIGS. 11 and 12, the phosphor body 32 is comparatively thin. For example, the phosphor body 32 is made of a polysiloxane as a matrix material with phosphor particles embedded therein, similar to the phosphor body 32 of FIG. 5. A thickness of the polysiloxane-based phosphor body 32 is, for example, only between 5 μm and 20 μm, inclusive.

In order to mechanically stabilize the phosphor body 32 and embed it efficiently in the frame 31, a window body 51 is optionally provided. The translucent window body 51 is made of glass or sapphire, for example. The phosphor body 32 and the window body 51 can be congruent when viewed from above. A thickness of the window body 51 is, for example, between 50 μm and 0.5 mm inclusive.

In all other respects, the explanations in FIGS. 1 to 10 apply in the same way to FIGS. 11 and 12, and vice versa.

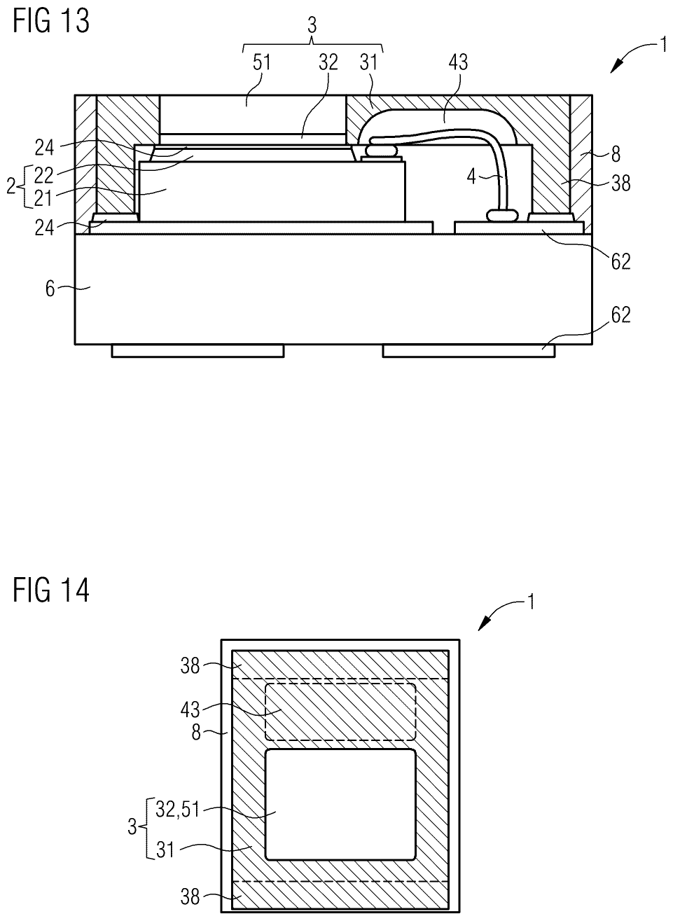

In the example of FIGS. 13 and 14, the frame 31 comprises a socket 38. The socket 38 is preferably made of the same material as the rest of the frame 31. It is possible that the socket 38 is attached to the rest of the frame 31, for example, glued or sintered on. In particular, the frame 31 is attached between the carrier 6 and the socket 38 by means of a connecting means 24.

For example, the socket 38 is formed by two cuboids that are located on two opposite sides of the carrier 6, as seen from above. This means that the two other sides can be free of the socket 38. Alternatively, the socket 38 can also be realized by several pillars, for example, by four separate pillars, so that one of the pillars is then located at each corner of the semiconductor component 1.

If the socket 38 is present, the plastic encapsulation 8 can be omitted. The socket 38 can improve the dissipation of heat loss from the light conversion process.

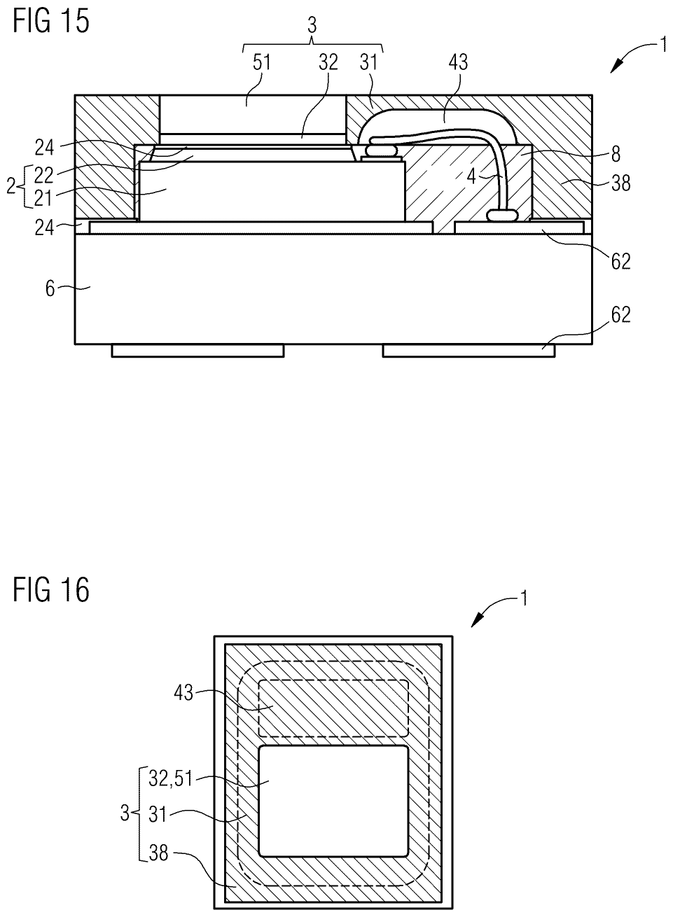

According to FIGS. 15 and 16, the socket 8 extends around the semiconductor chip 2. Thus, the ceramic frame 31 can form an upper part of a housing of the semiconductor component 1. A lower part of the housing is formed by the carrier 6.

Viewed from above, the socket 38 may comprise rounded inner corners, see FIG. 16.

Unlike in FIG. 13, the socket 38 of FIG. 15 is designed in one piece with the rest of the frame 31. This is also possible in the example of FIG. 13. Alternatively, the socket 38 and the rest of the frame 31 can also be joined together as shown in FIG. 15, analogously to FIG. 13.

Such sockets 38, as shown in FIGS. 13 to 16, may also be present in all other examples.

In all other respects, the explanations relating to FIGS. 1 to 12 apply in the same way to FIGS. 13 to 16, and vice versa.

FIGS. 9 to 16 each have recesses 43, as illustrated in FIGS. 3 and 4. However, recesses 43 as shown in FIGS. 7 and 8 can also be used in the same way.

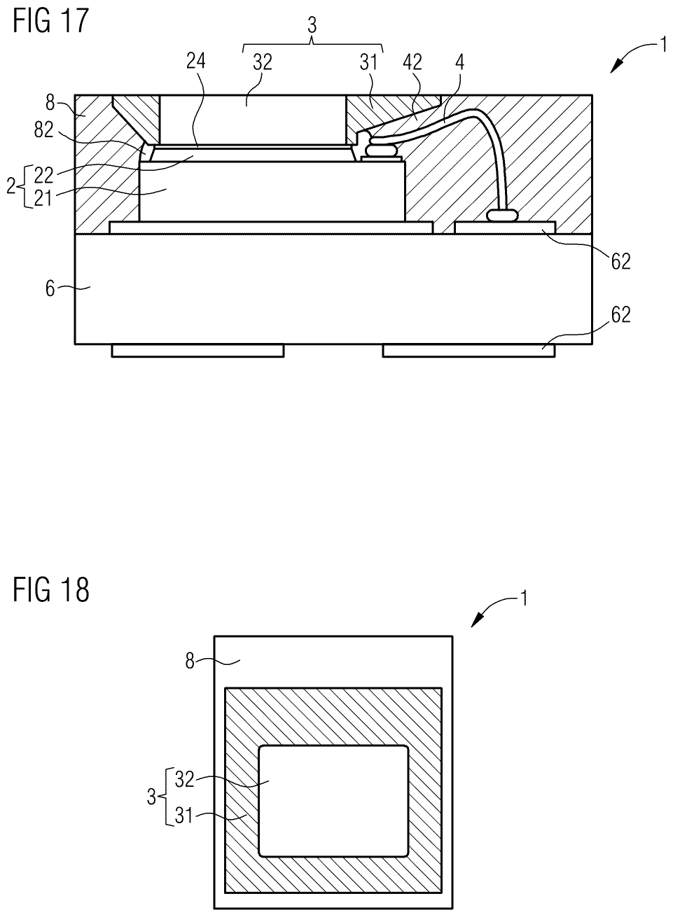

FIGS. 17 and 18 illustrate that, viewed in cross-section, the frame 31 comprises a trapezoidal or approximately trapezoidal outer contour. This means that the frame 31 can widen in the direction away from the semiconductor chip 2. In this case, the frame 31 can be asymmetrically shaped when viewed in cross-section. In the region of the at least one bonding wire 4, the frame 31 can thus comprise an undercut 42. In the area of the undercut 42, the frame 31 extends further away from the phosphor body 32 than in other areas.

Alternatively, instead of an undercut 42, a recess 43, for example, as shown in FIG. 3 or 7, can also be provided. Furthermore, it is possible that the frame 31 of FIGS. 17 and 18 is provided with a socket, not shown.

As a further option, the plastic encapsulation 8 of FIGS. 17 and 18 is black. For example, the plastic encapsulation 8 is then made of a silicone or an epoxy that is provided with a black colorant or with black pigments, such as carbon black. Alternatively, as in all other examples, the plastic encapsulation 8 can also be white.

Furthermore, it is possible that an edge encapsulation 82 is present on side surfaces of the connecting means 24 and/or the semiconductor layer sequence 22. For example, the edge encapsulation 82 extends from the chip substrate 21 to the plastic encapsulation 8. This can prevent the black plastic encapsulation 8 from absorbing radiation from the semiconductor chip 2. The edge encapsulation 82 is made of a silicone or epoxy, for example, in which reflective metal oxide particles are embedded.

In all other respects, the comments on FIGS. 1 to 16 apply in the same way to FIGS. 17 and 18, and vice versa.

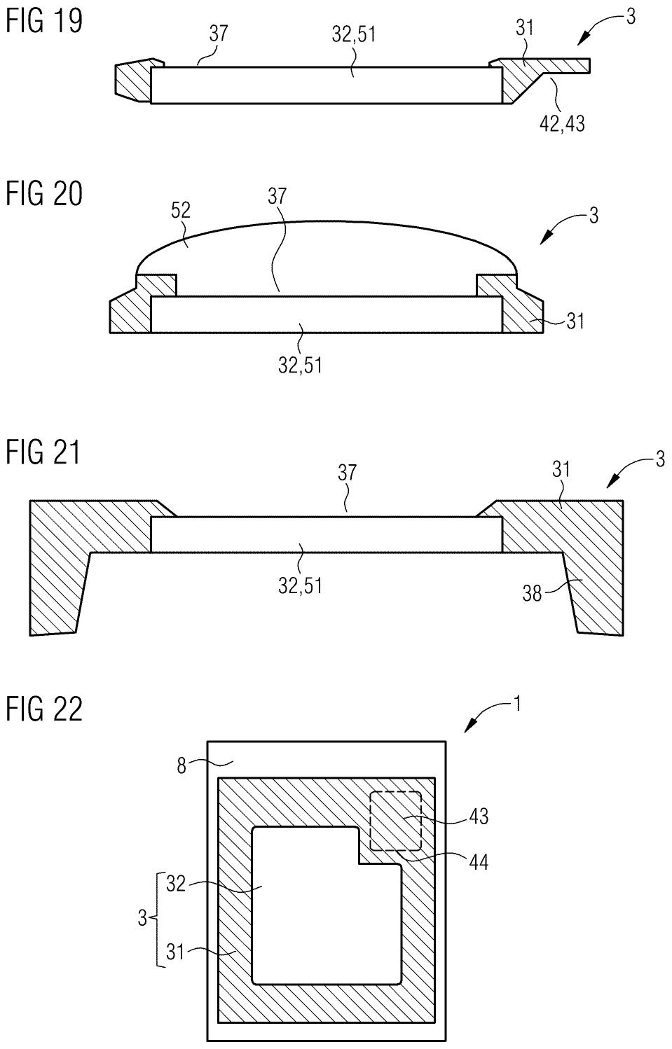

FIGS. 19 to 21 show various examples of the shape of a profile of the frame 31. According to FIG. 19, the frame 31 is approximately as thick as the phosphor body 32. The frame 31 extends to a main side of the phosphor body 32 facing away from the semiconductor chip 2, so that the cavity 37 is formed. The recess 43 or the undercut 42 is optionally present.

According to FIG. 20, the optical body 52, which is designed as a lens, is mounted in the cavity 37. The area of the frame 31 that rises above the phosphor body 32 can serve as a stop edge for casting the optical body 52. Such an optical body 52 and/or such a cavity 37 may also be present in all other examples.

In contrast to FIG. 19, the frame 31 of FIG. 20 has the same shape on both sides of the phosphor body 32, as seen along a longitudinal direction of the conversion element 3.

Finally, FIG. 21 illustrates that the frame comprises both the socket 38 and the cavity 37. This is also possible in all other examples.

In all other respects, the explanations relating to FIGS. 1 to 18 apply in the same way to FIGS. 19 to 21, and vice versa.

FIGS. 22 to 25 show top views of different variants of the semiconductor component 1, as is also possible in all other examples. According to FIG. 22, the phosphor body 32 comprises a cutout 44 at one corner. The recess 43 or the undercut 42, not shown, can be placed in this cutout 44 in the frame 31. Such a cutout 44 can also be present at two corners of the phosphor body 32.

FIG. 23 shows that several of the phosphor bodies 32 and optionally several of the recesses 43 are integrated in a single frame 31. The semiconductor component 1 can thus comprise several of the semiconductor chips 2, with each of the semiconductor chips 2 being assigned its own phosphor body 32.

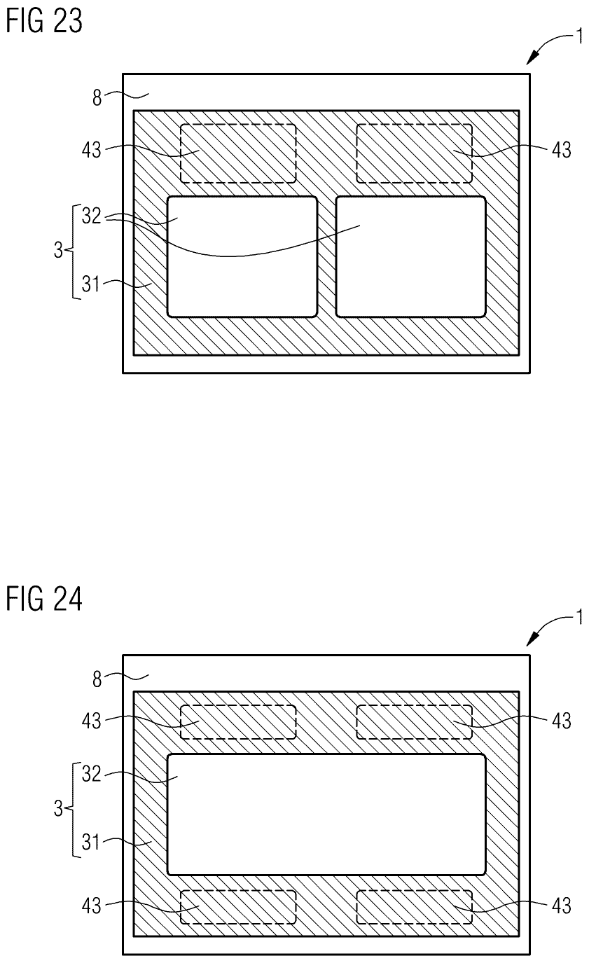

According to FIG. 24, several of the semiconductor chips 2 are also present, but all semiconductor chips 2 are covered by a common, large phosphor body 32. In contrast to the illustration, there may also be only a single recess 43 for all bonding wires.

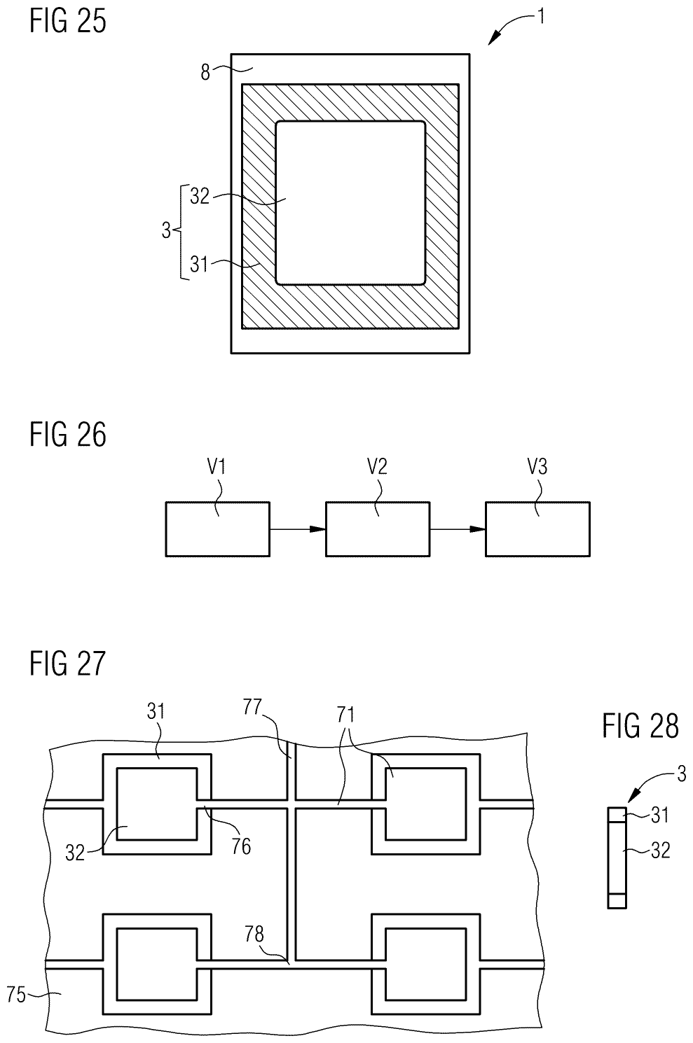

Finally, FIG. 25 illustrates that the phosphor body 32 can be rectangular in shape when viewed from above. Corners can be rounded. The semiconductor component 1 of FIG. 25 is in particular free of recesses 43 or undercuts 42, so that the semiconductor chip 2 is in particular a flip chip.

In all other respects, the explanations relating to FIGS. 1 to 21 apply in the same way to FIGS. 22 to 25, and vice versa.

FIG. 26 schematically shows a manufacturing process for semiconductor components 1. In a first step V1, a plurality of phosphor bodies 32 are provided. Subsequently or alternatively preceding, a plurality of frames 31 are provided in a step V2. Finally, in step V3, the frames are separated to form the conversion elements 3. FIGS. 27 to 37 show different variants of the manufacturing process in more detail.

In the method of FIGS. 27 and 28, a second composite 72 is first produced with the frames 31, in particular with the aid of a first mold, not shown. The individual frames 31 are still connected to each other via sprues. The frames 31 each comprise an opening for a sprue point 76. The frames 31 are present, for example, as green compacts or as dried engobe.

In the step shown in FIG. 27, a material for the phosphor bodies 32 is then filled into the previously created frames 31 via the further casting channels 77, for example, by casting or pressing, so that a first bond 71 with the phosphor bodies 32 is formed. Both the frames 31 and a mold 75 are used to shape the phosphor bodies 32, which are present in particular as green bodies.

After sintering and separating, the result is the conversion elements 3, see also FIG. 28. Any material remaining in the casting channels is then no longer present.

However, the method shown in FIGS. 27 and 28 results in undesirable light spots at the sprue points 76 in the finished semiconductor components 1. In addition, the additional casting channels 77 consume a comparatively large amount of material of the phosphor bodies 32.

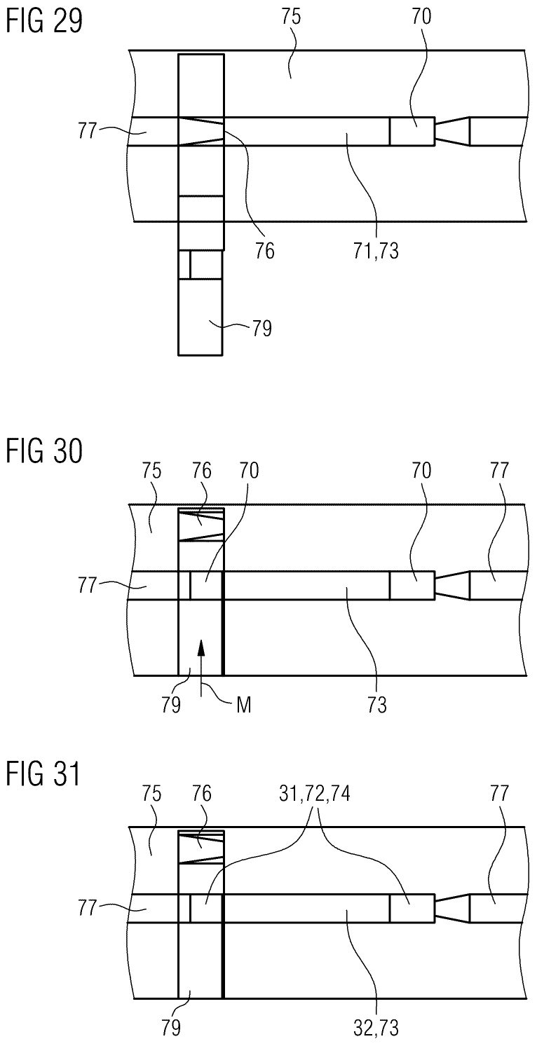

In the method of FIGS. 29 to 31, the first composite 71 is therefore first produced with the green bodies 73, see FIG. 29. In the method of FIGS. 29 to 31, high-pressure casting or injection molding is used in particular.

Subsequently, see FIG. 30, the sprue points 76 are removed by means of a pusher 79. The pusher 79 preferably moves along a direction of movement M perpendicular to a plane with the green bodies 73. The green bodies 73 remain in the mold 75.

The pusher 79 also comprises a region 70 for the second compound 72.

In the step shown in FIG. 31, the material for the engobes 74 of the frames 31 of the second composite 72 is then filled in. As an alternative to an engobe, the frames 31 can also be in the form of green bodies. After removing the mold 75, not shown, the composites 71, 72 can be sintered and then separated, or vice versa. The ceramic frames 31 can be cast onto green bodies 73 as well as onto already sintered phosphor bodies 32.

In all other respects, the explanations relating to FIGS. 1 to 25 apply in the same way to FIGS. 26 to 31, and vice versa.

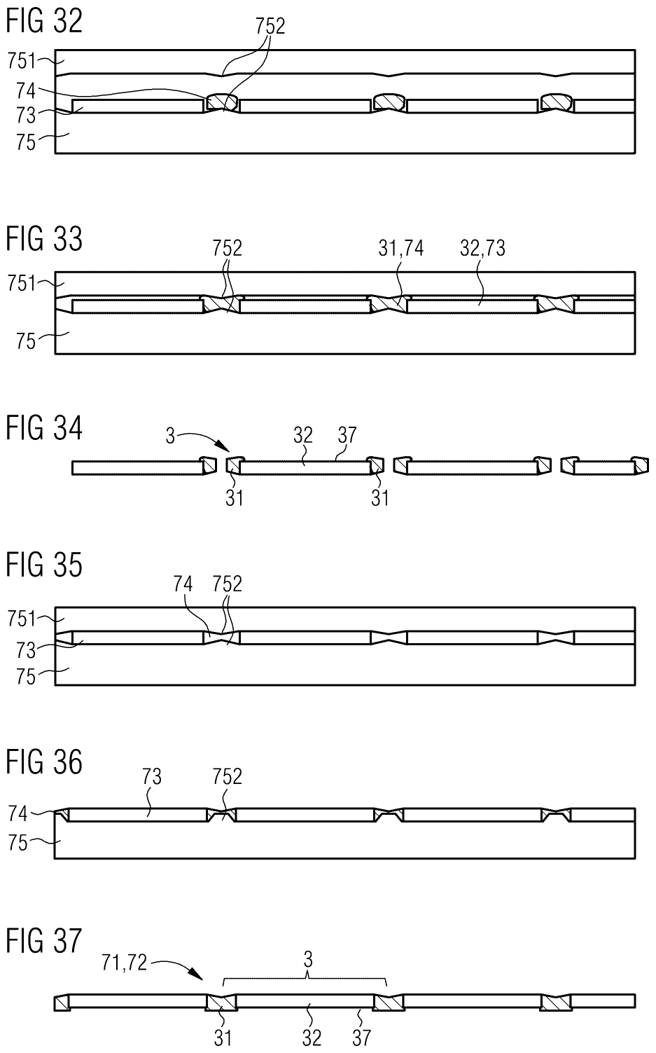

In the method of FIGS. 32 to 34, a two-part mold 75, 751 is used. The materials for the frames 31 and for the phosphor bodies 32 are placed in the first part 75 of the mold. The materials can be viscous, thin or paste-like, as long as the materials are not mixed too much. For example, a material for the frames 31 is present as a paste and the thinner material for the phosphor bodies 32 is then filled into the corresponding gaps, or vice versa.

The mold 75, 751 optionally comprises ridges 752. The ridges 752 lead to material tapering in the area of the frames 31, resulting in predetermined breaking points for subsequent separation, see the step of pressing the mold 75, 751 together as shown in FIG. 33.

Either still in the mold 75, 751 or after removing the mold 75, 751, sintering takes place. The individual conversion elements 3 are then produced by separating them along the predetermined breaking points, see FIG. 34.

In all other respects, the explanations relating to FIGS. 26 to 31 apply in the same way to FIGS. 32 to 34, and vice versa.

In the method of FIG. 35, for example, a closed mold 75, 751 made of plaster is used. First, the green bodies 73 for the phosphor bodies 32 are produced and placed in the mold 75, 751 or produced in the mold 75, 751. Slurry for the frames 31 is then filled in and dried, resulting in an engobe 74 for the frames 31, for example. After demolding, that is, removing the mold 75, 751, a joint sintering process is carried out in which the frames 31 and the phosphor bodies 32 are sintered together. Finally, separation is carried out again, not shown.

In all other respects, the explanations for FIGS. 26 to 34 apply in the same way to FIG. 35, and vice versa.

In the method of FIGS. 36 and 37, an open mold 75, for example, made of plaster, is used. First, the green bodies 73 for the phosphor bodies 32 are inserted. Then a slip for the engobes 74 of the frames is poured in and dried, see FIG. 36.

After demolding, see FIG. 37, the green bodies 73 and engobe 74 are sintered, after which they are separated to form the conversion elements 3. Separation is, for example, cutting, breaking or sawing. Alternatively, it is possible for the separation to be carried out before sintering.

In all other respects, the explanations relating to FIGS. 26 to 35 apply in the same way to FIGS. 36 and 37, and vice versa.

The components shown in the figures preferably follow one another in the order indicated, in particular directly one after the other, unless described otherwise. Components not touching each other in the figures preferably have a distance to each other. If lines are drawn parallel to each other, the associated surfaces are preferably also aligned parallel to each other. Furthermore, the relative positions of the drawn components to each other are correctly shown in the figures, unless otherwise specified.

The invention described herein is not limited by the description based on the exemplary embodiments. Rather, the invention includes any new feature as well as any combination of features, which includes in particular any combination of features in the patent claims, even if this feature or combination itself is not explicitly specified in the patent claims or exemplary embodiments.

This patent application claims the priority of the German patent application 10 2022 101 910.1, the disclosure content of which is hereby incorporated by reference.

### LIST OF REFERENCE SIGNS

1 optoelectronic semiconductor component
2 optoelectronic semiconductor chip
20 main radiation side
21 chip substrate
22 semiconductor layer sequence
24 connecting means
3 conversion element
31 frame
32 phosphor body
33 phosphor particle
34 matrix material
35 base material
36 admixture
37 cavity
38 socket
4 bond wire
41 contact points
42 undercut
43 recess
44 cutout
51 window body
52 optical body
6 carrier
62 electrical connection surface
70 region for the second compound
71 first composite with the phosphor bodies
72 second composite with the frames
73 green body
74 engobe
75 mold
751 mold cover
752 ridge
76 sprue point
77 casting channel
78 surplus material of the phosphor body
5 79 pusher
8 plastic encapsulation
82 edge encapsulation
9 modification of a semiconductor component
M direction of movement
10 P primary radiation
S secondary radiation
V process step

1. An optoelectronic semiconductor component comprising
an optoelectronic semiconductor chip,
at least one bonding wire with which the optoelectronic semiconductor chip is electrically contacted, and
a conversion element which is configured to convert at least part of a primary radiation emitted by the optoelectronic semiconductor chip during operation into a secondary radiation, wherein
the conversion element comprises a frame and a phosphor body within the frame,
the phosphor body comprises at least one phosphor and the frame comprises at least one ceramic,
the frame is in direct contact with the phosphor body in a lateral direction which is oriented parallel to a main radiation side of the optoelectronic semiconductor chip,
the frame comprises at least one recess and the bonding wire is located at least partially in the recess and, seen in plan view, the recess is located adjacent to the phosphor body, and
the recess only partially penetrates the frame in a direction perpendicular to the main radiation side.

2. The optoelectronic semiconductor component according to claim 1,
wherein
the frame directly surrounds the phosphor body all around as seen in plan view of the main radiation side, and
the ceramic of the frame is opaque.

3. The optoelectronic semiconductor component according to claim 1,
wherein the ceramic comprises Al₂O₃ or AlN as a base material and contains an admixture or pores acting reflectively for the primary radiation and/or the secondary radiation,
wherein the admixture is at least one metal oxide, in particular ZrO₂ and/or TiO₂.

4. The optoelectronic semiconductor component according to claim 1,
wherein the frame partially covers the main radiation side when viewed from above and the frame projects beyond the optoelectronic semiconductor chip all around.

5. The optoelectronic semiconductor de according to claim 1,
wherein the recess, in a direction perpendicular to the main radiation side, extends at least 50% and at most 90% through the frame.

6. The optoelectronic semiconductor component according to claim 5,
wherein in the recess the at least one bonding wire runs parallel to the main radiation side, with a tolerance of at most 45°.

7. The optoelectronic semiconductor component according to claim 5,
wherein the recess is surrounded all around by a material of the frame, as seen in plan view of the radiation main side and over a whole thickness of the frame.

8. The optoelectronic semiconductor component according to claim 1,
wherein the frame comprises a cavity on a side of the phosphor body facing away from the optoelectronic semiconductor chip, and the frame surrounds the cavity all around in a lateral direction.

9. The optoelectronic semiconductor component according to claim 8,
further comprising a window body, wherein
the window body is transparent at least for the secondary radiation,
the phosphor body is mounted directly on the window body, and
the window body is in direct contact with the frame in the lateral direction.

10. The optoelectronic semiconductor component according to claim 8,
further comprising an optical body, wherein
the optical body is transparent at least for the secondary radiation, and
the optical body at least partially fills and at least partially covers the cavity.

11. The optoelectronic semiconductor component according to claim 1,
wherein the cavity and/or the frame widens in a direction away from the optoelectronic semiconductor chip.

12. The optoelectronic semiconductor component according to claim 1,
further comprising a carrier,
wherein the frame comprises a socket, and
wherein the socket and the optoelectronic semiconductor chip are mounted together on the carrier.

13. The optoelectronic semiconductor component according to claim 1,
wherein the phosphor body comprises at least one ceramic,
wherein a thickness of the phosphor body is between 30 μm and 0.5 mm, inclusive.

14. The optoelectronic semiconductor component according to claim 1,
wherein the phosphor body comprises at least one polysiloxane as a matrix material and phosphor particles comprising the at least one phosphor embedded therein,
wherein a thickness of the phosphor body is between 5 μm and 30 μm, inclusive.

15. A conversion element for an optoelectronic semiconductor component, wherein
the conversion element is configured to convert at least a portion of a primary radiation emitted by an optoelectronic semiconductor chip during operation into a secondary radiation,
the conversion element comprises a frame and a phosphor body within the frame,
the phosphor body comprises at least one phosphor and the frame contains at least one ceramic,
the frame is in direct contact with the phosphor body in a lateral direction,
the conversion element is configured to be operated in transmission,
the frame comprises at least one recess which is provided for a bonding wire and the recess is located next to the phosphor body, and
the recess only partially runs through the frame.

16. A method for producing an optoelectronic semiconductor component according to claim 1, comprising the following steps:
A) providing a plurality of the phosphor bodies,
B) providing a plurality of the frames,
C) separating into the conversion elements.

17. The method according to claim 16,
wherein steps A), B) and C) are carried out in the order given, and
wherein the phosphor bodies and the frames are sintered together.

18. The method according to claim 16,
wherein the step A) comprises
A1) providing a first composite with a plurality of the phosphor bodies,
A2) separating the first composite into the individual phosphor bodies, wherein relative positions of the phosphor bodies to each other are maintained until after the step B),
wherein the step B) comprises:
B1) providing a second composite with a plurality of the frames directly on the previously provided phosphor bodies.

19. The method according to claim 16, wherein the step A) comprises:
A3) providing individual green bodies for the phosphor bodies,
A4) placing the green bodies in a mold,
wherein the step B) comprises:
B2) forming an engobe around the green bodies in the mold.

20. The optoelectronic semiconductor component according to claim 1,
wherein
a thickness of the frame is greater than or equal to a thickness of the phosphor body,
the conversion element is configured to be passed by the primary radiation and/or by the secondary radiation in a direction transverse to the main radiation side, and
a reflectivity of the ceramic of the frame is at least 95% at least for the secondary radiation.
